(19) United States
(12) Patent Application Publication
(10) Pub. No.: US 2018/0322840 A1
(43) Pub. Date: Nov. 8, 2018

(54) SHIFT REGISTER CIRCUIT AND DISPLAY PANEL USING SAME

(71) Applicants: HKC Corporation Limited, Shenzhen City, Guangdong (CN); Chongqing HKC Optoelectronics Technology Co., Ltd., Chongqing (CN)

(72) Inventor: Yu-Jen CHEN, Chongqing (CN)

(73) Assignees: HKC Corporation Limited, Shenzhen City, Guangdong (CN); Chongqing HKC Optoelectronics Technology Co., Ltd., Chongqing (CN)

(21) Appl. No.: 15/555,891

(22) PCT Filed: May 17, 2017
(86) PCT No.: PCT/CN2017/084673

§ 371 Date: Sep. 5, 2017

(30) Foreign Application Priority Data
May 5, 2017 (CN) 201710313146.5

(51) Int. Cl. G09G 3/36; G11C 19/28

(52) U.S. Cl. CPC G09G 3/3677; G09G 2310/06; G09G 2310/0286; G11C 19/28

(57) ABSTRACT

A shift register circuit includes shift registers, each including: a first through fourth switches. In the first switch: a control end electrically coupled to a first node, a first end coupled to a frequency signal, and a second end electrically coupled to an output pulse signal; in the second switch: a control end electrically coupled to a control signal, a first end electrically coupled to the control signal, and a second end electrically coupled to the first node; in the third switch: a control end electrically coupled to the first node, a first end electrically coupled to the frequency signal, and a second end of electrically coupled to a control signal; in the fourth switch: a control end electrically coupled to the first node, a first end electrically coupled to the frequency signal, and a second end electrically coupled for generating a feedback signal.

### BACKGROUND

### Technical Field

This application relates to a circuit structure in a display, and in particular, to a shift register circuit and a display panel using the same.

### Related Art

In recent years, with progress of science and technologies, flat liquid crystal displays gradually become popular and have advantages such as lightness and slimness. Currently, a driver circuit of a flat liquid crystal display is formed by connecting an external IC to a panel. However, this method cannot lower product costs or make the panel slimmer.

In addition, a liquid crystal display device usually includes a gate driver circuit, a source driver circuit, and a pixel array. The pixel array includes a plurality of pixel circuits. Each pixel circuit is switched on or off according to a scanning signal provided by the gate driver circuit. A data screen is displayed according to a data signal provided by the source driver circuit. With regard to the gate driver circuit, the gate driver circuit usually includes a plurality of stages of shift registers and outputs the scanning signal to the pixel array by transferring the scanning signal from a current-stage shift register to a next-stage shift register, so as to sequentially switch on the pixel circuits and enable the pixel circuits to receive the data signal.

Therefore, in a manufacturing process of a driver circuit, a gate driver circuit is directly manufactured on an array substrate to replace a driver chip made from a connected external IC. Such a technology, referred to as Gate On Array (GOA), may be directly applied to a periphery of a panel, to reduce manufacturing procedures, product costs, and a thickness of the panel. However, pulling down a potential is alternately controlled by two groups of signals in the existing GOA technology, and a duty cycle is 50%. In this case, transistors responsible for pulling down the potential are in a positive voltage state for a long time and cannot get enough rest. As a result, reliability of the transistors rapidly degrades, further directly leading to low display quality or even damage to a display device. Therefore, to alleviate disadvantages of the foregoing conventional GOA circuit substrate technology, a gate array shift register having low manufacturing costs and an easy processing procedure is provided.

### SUMMARY

To resolve the foregoing technical problem, an objective of this application is to provide a shift register circuit. An active switch specifically responsible for generating a feedback signal is newly added into the shift register circuit. The active switch is only responsible for controlling a feedback signal, and the feedback signal does not need to pass through a load of a main circuit, so that a waveform is prevented from decreasing. Reliability of a product can be improved and a service life of the product can be prolonged.

The objective of this application is achieved and the technical problem of this application is resolved by using the following technical solutions. A shift register circuit is provided according to this application, comprising a plurality of stages of shift registers, where each shift register comprises: a first switch, where a control end of the first switch is electrically coupled to a first node, a first end of the first switch is electrically coupled to a frequency signal, and a second end of the first switch is electrically coupled to an output pulse signal; a second switch, where a control end of the second switch is electrically coupled to a control signal, a first end of the second switch is electrically coupled to the control signal, and a second end of the second switch is electrically coupled to the first node; a third switch, where a control end of the third switch is electrically coupled to the first node, a first end of the third switch is electrically coupled to the frequency signal, and a second end of the third switch is electrically coupled to a control signal; and a fourth switch, where a control end of the fourth switch is electrically coupled to the first node, a first end of the fourth switch is electrically coupled to the frequency signal, and a second end of the fourth switch is electrically coupled for generating a feedback signal.

Another objective of this application is to provide a liquid crystal display panel, comprising: a first substrate; a second substrate, disposed opposite to the first substrate; a liquid crystal layer, disposed between the first substrate and the second substrate; a shift register circuit, disposed on the first substrate or the second substrate. In addition, the liquid crystal display panel further comprises a first polarizer, disposed on an outer surface of the first substrate; and a second polarizer, disposed on an outer surface of the second substrate, where a polarization direction of the first polarizer is parallel to a polarization direction of the second polarizer.

The technical problem of this application may be further resolved by using the following technical solutions.

In an embodiment of this application, a first pull-down circuit is further comprised, where the first pull-down circuit comprises a fifth switch, where a control end of the fifth switch is electrically coupled to a feedback signal, a first end of the fifth switch is electrically coupled to the first node, and a second end of the fifth switch is electrically coupled to a preset low potential.

In an embodiment of this application, the first pull-down circuit is configured to pull down a potential of the control end of the fifth switch.

In an embodiment of this application, a second pull-down circuit is further comprised, where the second pull-down circuit comprises a sixth switch and a seventh switch, where a control end of the sixth switch is electrically coupled to a second node, a first end of the sixth switch is electrically coupled to the output pulse signal, and a second end of the sixth switch is electrically coupled to the preset low potential.

In an embodiment of this application, a control end of the seventh switch is electrically coupled to a second node, a first end of the seventh switch is electrically coupled to the first node, and a second end of the seventh switch is electrically coupled to the preset low potential.

In an embodiment of this application, the second pull-down circuit is configured to pull down a potential of the control end of the sixth switch.

In an embodiment of this application, a third pull-down circuit is further comprised, where the third pull-down circuit comprises an eighth switch and a ninth switch, where a control end of the eighth switch is electrically coupled to a third node, a first end of the eighth switch is electrically coupled to the output pulse signal, and a second end of the eighth switch is electrically coupled to the preset low potential.

In an embodiment of this application, a control end of the ninth switch is electrically coupled to a third node, a first end of the ninth switch is electrically coupled to the first node, and a second end of the ninth switch is electrically coupled to the preset low potential.

In an embodiment of this application, the third pull-down circuit is configured to pull down a potential of the control end of the eighth switch.

In an embodiment of this application, a pull-down circuit controller is further comprised, and is electrically coupled to a low-frequency signal, a third node, the feedback signal, and the preset low potential in the shift register.

In this application, an active switch specifically responsible for generating a feedback signal is newly added. The active switch is only responsible for controlling a feedback signal, and the feedback signal does not need to pass through a load of a main circuit, so that a waveform is prevented from decreasing. Reliability of a product can be improved and a service life of the product can be prolonged.

### BRIEF DESCRIPTION OF THE DRAWINGS

FIG. 1a is a schematic diagram of an exemplary liquid crystal display;

FIG. 1b is a schematic diagram of a liquid crystal display according to an embodiment of this application;

FIG. 2a is a schematic diagram of an exemplary shift register circuit;

FIG. 2b is a schematic diagram of a shift register circuit according to an embodiment of this application; and

FIG. 3 is a schematic diagram of a liquid crystal display panel according to another embodiment of this application.

### DETAILED DESCRIPTION

The following embodiments are described with reference to the accompanying drawings, used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, modules with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout the specification, “on” means that one is located above or below a target component and does not necessarily mean that one is located on the top based on a gravity direction.

To further describe the technical measures taken in this application to achieve the intended application objective and effects thereof, specific implementations, structures, features, and effects of a shift register circuit and a display panel using same provided according to this application are described below in detail with reference to the drawings and preferred embodiments.

A liquid crystal panel in this application may include: an active array (thin film transistor (TFT)) substrate, a color filter (CF) substrate, and a liquid crystal layer formed between the two substrates.

In an embodiment, the liquid crystal panel in this application may be a curved-surface display panel.

In an embodiment, the active array (TFT) and the CF in this application may be formed on a same substrate.

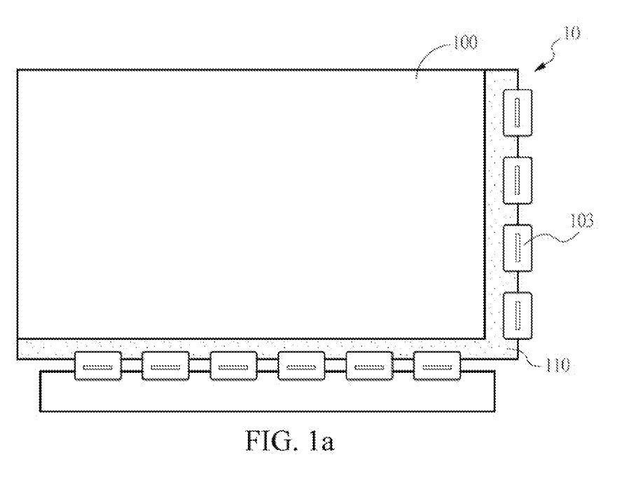

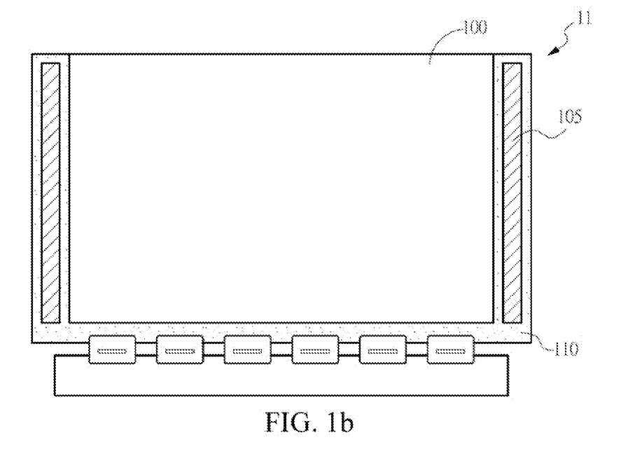

FIG. 1a is a schematic diagram of an exemplary liquid crystal display. Referring to FIG. 1a, a liquid crystal display 10 includes: a CF substrate 100, an active array substrate 110, and a driver chip 103 configured to drive a circuit.

FIG. 1b is a schematic diagram of a liquid crystal display according to an embodiment of this application. Referring to FIG. 1b, in an embodiment of this application, a liquid crystal display 11 having a GOA includes: a CF substrate 100, an active array substrate 110, and a GOA 105, configured to manufacture a gate driver circuit on the array substrate 110.

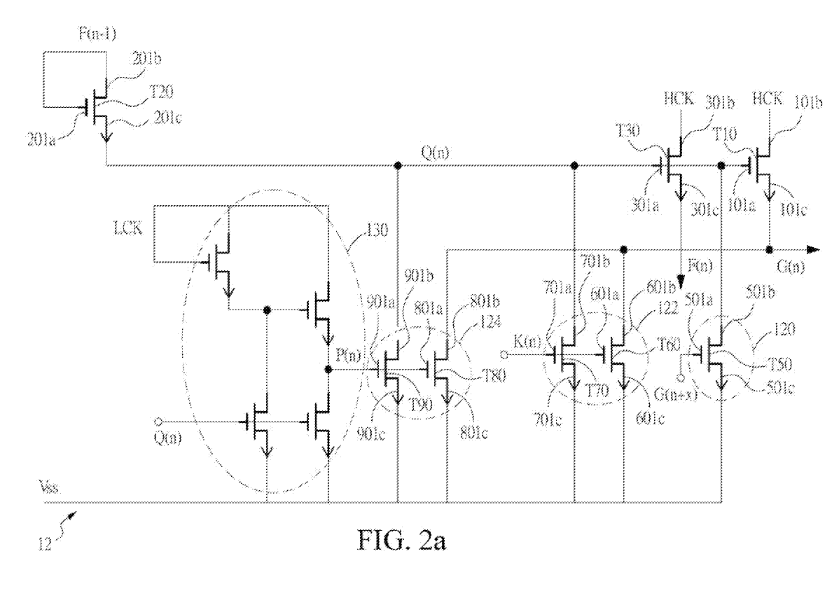

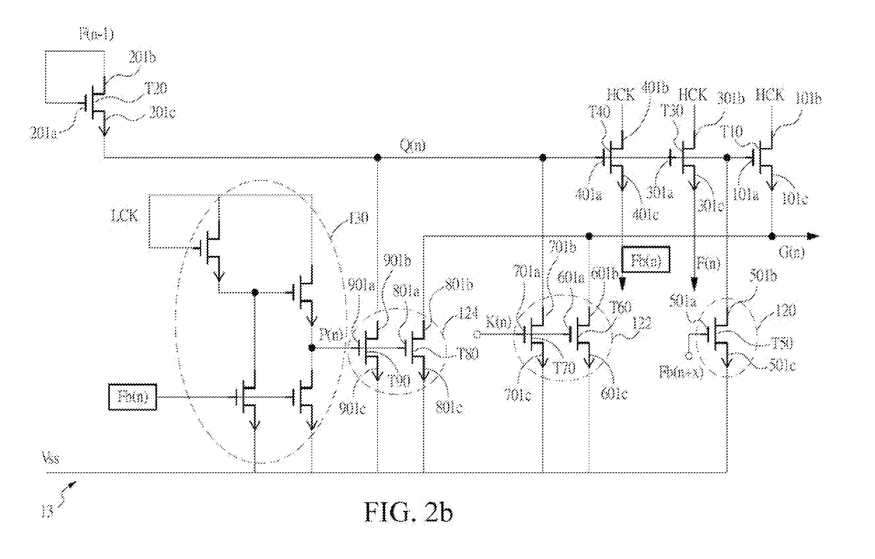

FIG. 2a is a schematic diagram of an exemplary shift register circuit. Referring to FIG. 2a, a shift register circuit 12 includes a plurality of stages of shift registers, where each shift register includes: a first switch T10, where a control end 101a of the first switch T10 is electrically coupled to a first node Q(n), a first end 101b of the first switch T10 is electrically coupled to a frequency signal HCK, and a second end 101c of the first switch T10 is electrically coupled to an output pulse signal G(n); a second switch T20, where a control end 201a of the second switch T20 is electrically coupled to a control signal F(n-1), a first end 201b of the second switch T20 is electrically coupled to the control signal F(n-1), and a second end 201c of the second switch T20 is electrically coupled to the first node Q(n); and a third switch T30, where a control end 301a of the third switch T30 is electrically coupled to the first node Q(n), a first end 301b of the third switch T30 is electrically coupled to the frequency signal HCK, and a second end of 301c the third switch T30 is electrically coupled to a control signal F(n).

In an embodiment, a first pull-down circuit 120 is further included, where the first pull-down circuit 120 includes a fifth switch T50, where a control end 501a of the fifth switch T50 is electrically coupled to an output pulse signal G(n+x), a first end 501b of the fifth switch T50 is electrically coupled to the first node Q(n), and a second end 501c of the fifth switch T50 is electrically coupled to the preset low potential Vss.

In an embodiment, the first pull-down circuit 120 is configured to pull down a potential of the control end 501a of the fifth switch T50.

In an embodiment, a second pull-down circuit 122 is further included, where the second pull-down circuit 122 includes a sixth switch T60 and a seventh switch T70, where a control end 601a of the sixth switch T60 is electrically coupled to a second node K(n), a first end 601b of the sixth switch T60 is electrically coupled to the output pulse signal G(n), and a second end 601c of the sixth switch T60 is electrically coupled to the preset low potential Vss.

In an embodiment, a control end 701a of the seventh switch T70 is electrically coupled to a second node K(n), a first end 701b of the seventh switch T70 is electrically coupled to the first node Q(n), and a second end of 701c the seventh switch T70 is electrically coupled to the preset low potential Vss.

In an embodiment, the second pull-down circuit 122 is configured to pull down a potential of the control end 601a of the sixth switch T60.

In an embodiment, a third pull-down circuit 124 is further included, where the third pull-down circuit 124 includes an eighth switch T80 and a ninth switch T90, where a control end 801a of the eighth switch T80 is electrically coupled to a third node P(n), a first end 801b of the eighth switch T80 is electrically coupled to the output pulse signal G(n), and a second end 801c of the eighth switch T80 is electrically coupled to the preset low potential Vss.

In an embodiment, a control end 901a of the ninth switch T90 is electrically coupled to a third node P(n), a first end 901b of the ninth switch T90 is electrically coupled to the first node Q(n), and a second end of 901c the ninth switch T90 is electrically coupled to the preset low potential Vss.

In an embodiment, the third pull-down circuit 124 is configured to pull down a potential of the control end 801a of the eighth switch T80.

In an embodiment, a pull-down circuit controller 130 is further included, and is electrically coupled to a low-frequency signal LCK, a third node P(n), the first node Q(n), and the preset low potential Vss in the shift register.

FIG. 2b is a schematic diagram of a shift register circuit according to an embodiment of this application. Referring to FIG. 2b, a shift register circuit 13 in this application includes a plurality of stages of shift registers, where each shift register includes:

a first switch T10, where a control end 101a of the first switch T10 is electrically coupled to a first node Q(n), a first end 101b of the first switch T10 is electrically coupled to a frequency signal HCK, and a second end 101c of the first switch T10 is electrically coupled to an output pulse signal G(n); a second switch T20, where a control end 201a of the second switch T20 is electrically coupled to a control signal F(n-1), a first end 201b of the second switch T20 is electrically coupled to the control signal F(n-1), and a second end 201c of the second switch T20 is electrically coupled to the first node Q(n); a third switch T30, where a control end 301a of the third switch T30 is electrically coupled to the first node Q(n), a first end 301b of the third switch T30 is electrically coupled to the frequency signal HCK, and a second end of 301c the third switch T30 is electrically coupled to a control signal F(n); and a fourth switch T40, where a control end 401a of the fourth switch T40 is electrically coupled to the first node Q(n), a first end 401b of the fourth switch T40 is electrically coupled to the frequency signal HCK, and a second end 401c of the fourth switch T40 is electrically coupled for generating a feedback signal Fb(n).

In an embodiment, a first pull-down circuit 120 is further included, where the first pull-down circuit 120 includes a fifth switch T50, where a control end 501a of the fifth switch T50 is electrically coupled to a feedback signal Fb(n+x), a first end 501b of the fifth switch T50 is electrically coupled to the first node Q(n), and a second end 501c of the fifth switch T50 is electrically coupled to the preset low potential Vss.

In an embodiment, the first pull-down circuit 120 is configured to pull down a potential of the control end 501a of the fifth switch T50.

In an embodiment, a second pull-down circuit 122 is further included, where the second pull-down circuit 122 includes a sixth switch T60 and a seventh switch T70, where a control end 601a of the sixth switch T60 is electrically coupled to a second node K(n), a first end 601b of the sixth switch T60 is electrically coupled to the output pulse signal G(n), and a second end 601c of the sixth switch T60 is electrically coupled to the preset low potential Vss.

In an embodiment, a control end 701a of the seventh switch T70 is electrically coupled to the second node K(n), a first end 701b of the seventh switch T70 is electrically coupled to the first node Q(n), and a second end of 701c the seventh switch T70 is electrically coupled to the preset low potential Vss.

In an embodiment, the second pull-down circuit 122 is configured to pull down a potential of the control end 601a of the sixth switch T60.

In an embodiment, a third pull-down circuit 124 is further included, where the third pull-down circuit 124 includes an eighth switch T80 and a ninth switch T90, where a control end 801a of the eighth switch T80 is electrically coupled to a third node P(n), a first end 801b of the eighth switch T80 is electrically coupled to the output pulse signal G(n), and a second end 801c of the eighth switch T80 is electrically coupled to the preset low potential Vss.

In an embodiment, a control end 901a of the ninth switch T90 is electrically coupled to a third node P(n), a first end 901b of the ninth switch T90 is electrically coupled to the first node Q(n), and a second end of 901c the ninth switch T90 is electrically coupled to the preset low potential Vss.

In an embodiment, the third pull-down circuit 124 is configured to pull down a potential of the control end 801a of the eighth switch T80.

In an embodiment, a pull-down circuit controller 130 is further included, and is electrically coupled to a low-frequency signal LCK, a third node P(n), the feedback signal Fb(n), and the preset low potential Vss in the shift register.

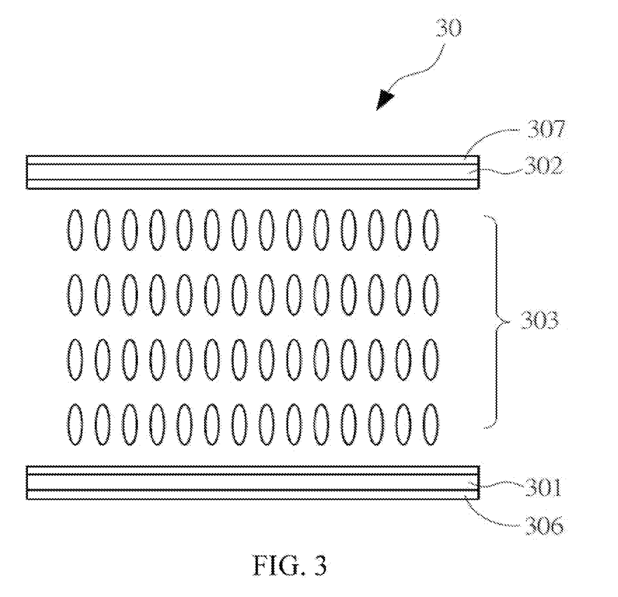

FIG. 3 is a schematic diagram of a liquid crystal display panel according to another embodiment of this application. Referring to FIG. 3 and FIG. 2b, in an embodiment of this application, a liquid crystal display panel 30 includes a first substrate 301 (for example, an active array substrate); a second substrate 302 (for example, a CF substrate), disposed opposite to the first substrate 301; and a liquid crystal layer 303, disposed between the first substrate 301 and the second substrate 302. In addition, the liquid crystal display panel 30 also includes the shift register circuit 13, disposed between the first substrate 301 and the second substrate 302 (for example, located on a surface of the first substrate 301). Moreover, the liquid crystal display panel 30 further includes a first polarizer 306, disposed on an outer surface of the first substrate 301; and a second polarizer 307, disposed on an outer surface of the second substrate 302, where a polarization direction of the first polarizer 306 is parallel to a polarization direction of the second polarizer 307.

In this application, an active switch specifically responsible for generating a feedback signal is newly added. The active switch is only responsible for controlling a feedback signal, and the feedback signal does not need to pass through a load of a main circuit, so that a waveform is prevented from decreasing. Reliability of a product can be improved and a service life of the product can be prolonged.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof

The foregoing descriptions are merely preferred embodiments of this application, and are not intended to limit this application in any form. Although this application has been disclosed above through the preferred embodiments, the embodiments are not intended to limit this application. Any person skilled in the art can make some variations or modifications, namely, equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A shift register circuit, comprising a plurality of stages of shift registers, wherein each shift register comprises:
a first switch, wherein a control end of the first switch is electrically coupled to a first node, a first end of the first switch is electrically coupled to a frequency signal, and a second end of the first switch is electrically coupled to an output pulse signal;
a second switch, wherein a control end of the second switch is electrically coupled to a control signal, a first end of the second switch is electrically coupled to the control signal, and a second end of the second switch is electrically coupled to the first node;
a third switch, wherein a control end of the third switch is electrically coupled to the first node, a first end of the third switch is electrically coupled to the frequency signal, and a second end of the third switch is electrically coupled to a control signal; and
a fourth switch, wherein a control end of the fourth switch is electrically coupled to the first node, a first end of the fourth switch is electrically coupled to the frequency signal, and a second end of the fourth switch is electrically coupled for generating a feedback signal.

2. The shift register circuit according to claim 1, further comprising a first pull-down circuit, wherein the first pull-down circuit comprises a fifth switch, wherein a control end of the fifth switch is electrically coupled to a feedback signal, a first end of the fifth switch is electrically coupled to the first node, and a second end of the fifth switch is electrically coupled to a preset low potential.

3. The shift register circuit according to claim 2, wherein the first pull-down circuit is configured to pull down a potential of the control end of the fifth switch.

4. The shift register circuit according to claim 1, further comprising a second pull-down circuit, wherein the second pull-down circuit comprises a sixth switch and a seventh switch, wherein a control end of the sixth switch is electrically coupled to a second node, a first end of the sixth switch is electrically coupled to the output pulse signal, and a second end of the sixth switch is electrically coupled to a preset low potential.

5. The shift register circuit according to claim 4, wherein a control end of the seventh switch is electrically coupled to the second node, a first end of the seventh switch is electrically coupled to the first node, and a second end of the seventh switch is electrically coupled to a preset low potential.

6. The shift register circuit according to claim 4, wherein the second pull-down circuit is configured to pull down a potential of the control end of the sixth switch.

7. The shift register circuit according to claim 1, further comprising a third pull-down circuit, wherein the third pull-down circuit comprises an eighth switch and a ninth switch, wherein a control end of the eighth switch is electrically coupled to a third node, a first end of the eighth switch is electrically coupled to the output pulse signal, and a second end of the eighth switch is electrically coupled to a preset low potential.

8. The shift register circuit according to claim 7, wherein a control end of the ninth switch is electrically coupled to the third node, a first end of the ninth switch is electrically coupled to the first node, and a second end of the ninth switch is electrically coupled to the preset low potential.

9. The shift register circuit according to claim 7, wherein the third pull-down circuit is configured to pull down a potential of the control end of the eighth switch.

10. The shift register circuit according to claim 1, further comprising a pull-down circuit controller, electrically coupled to a low-frequency signal, a third node, the feedback signal, and a preset low potential in the shift register.

11. A liquid crystal display panel, comprising:
a first substrate;
a second substrate, disposed opposite to the first substrate;
a liquid crystal layer, disposed between the first substrate and the second substrate;
a first polarizer, disposed on an outer surface of the first substrate; and a second polarizer, disposed on an outer surface of the second substrate, wherein a polarization direction of the first polarizer is parallel to a polarization direction of the second polarizer; and
a shift register circuit, disposed on the first substrate or the second substrate.

12. The liquid crystal display panel according to claim 11, wherein the shift register circuit comprises:
a first switch, wherein a control end of the first switch is electrically coupled to a first node, a first end of the first switch is electrically coupled to a frequency signal, and a second end of the first switch is electrically coupled to an output pulse signal;
a second switch, wherein a control end of the second switch is electrically coupled to a control signal, a first end of the second switch is electrically coupled to the control signal, and a second end of the second switch is electrically coupled to the first node;
a third switch, wherein a control end of the third switch is electrically coupled to the first node, a first end of the third switch is electrically coupled to the frequency signal, and a second end of the third switch is electrically coupled to a control signal; and
a fourth switch, wherein a control end of the fourth switch is electrically coupled to the first node, a first end of the fourth switch is electrically coupled to the frequency signal, and a second end of the fourth switch is electrically coupled for generating a feedback signal.

13. The liquid crystal display panel according to claim 12, wherein the shift register circuit further comprises a first pull-down circuit, wherein the first pull-down circuit comprises a fifth switch, wherein a control end of the fifth switch is electrically coupled to a feedback signal, a first end of the fifth switch is electrically coupled to the first node, and a second end of the fifth switch is electrically coupled to the preset low potential.

14. The liquid crystal display panel according to claim 12, wherein the shift register circuit further comprises a second pull-down circuit, wherein the second pull-down circuit comprises a sixth switch and a seventh switch, wherein a control end of the sixth switch is electrically coupled to a second node, a first end of the sixth switch is electrically coupled to the output pulse signal, and a second end of the sixth switch is electrically coupled to the preset low potential.

15. The liquid crystal display panel according to claim 12, wherein the shift register circuit further comprises a third pull-down circuit, wherein the third pull-down circuit comprises an eighth switch and a ninth switch, wherein a control end of the eighth switch is electrically coupled to a third node, a first end of the eighth switch is electrically coupled to the output pulse signal, and a second end of the eighth switch is electrically coupled to the preset low potential.

16. The liquid crystal display panel according to claim 12, wherein the shift register circuit further comprises a pull-down circuit controller, electrically coupled to a low-frequency signal, a third node, the feedback signal, and the preset low potential in the shift register.
